(19) United States
(12) Patent Application Publication
(10) Pub. No.: US 2008/0144297 A1
(43) Pub. Date: Jun. 19, 2008

(54) STRUCTURE FOR MOUNTING BOARD

(75) Inventor: Takashi ASANO, Tokyo (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/762,205

(22) Filed: Jun. 13, 2007

(30) Foreign Application Priority Data
Dec. 19, 2006 (JP) 2006-341773

(51) Int. Cl. H05K 5/00

(52) U.S. Cl. 361/759

(57) ABSTRACT

A chassis has positioning plates which are perpendicular to each other formed by cutting and bending a plate material, attachment convex portions which are formed by press work of the plate material, and which are projected out in bending direction of the positioning plates, and L-shaped attachments. Aboard has a pair of slits into which a pair of the positioning plates inserted, and attachment holes. The board is positioned in two directions by a pair of the positioning plates, thereby the board can be positioned with a high degree of accuracy.

The present application is based on, and claims priority from, Japanese patent application No. 2006-341773, filed on Dec. 19, 2006, the entire contents of which are incorporated herein by reference.

### BACKGROUND OF THE INVENTION

1. Field of the Invention

One embodiment of the invention relates to a structure for mounting a board, more particularly to a structure for mounting a board which have function for positioning the board.

2. Description of the Related Art

For example, an information processing device which has a structure for mounting a board which position and mount the board on a mounting board member. This conventional technique is disclosed in the Japanese patent Kokai No. 2002-107697.

In the conventional information processing device which can be inputted characters, figures, etc. via a display panel with an input stylus, the display panel having a liquid crystal panel and a light guide plate is held on a holding member (the mounting board member), and an electromagnetic-induction-type tablet sensor board is mounted on the holding member. Since positions (coordinates) are inputted via the display panel with the input stylus, the tablet sensor hoard must be positioned on the liquid crystal panel with accuracy.

In the structure for mounting a board of the conventional information processing device, the holding member is formed in horizontally elongate and substantially rectangular shape, has a plurality of positioning ribs integrally formed on both a lower edge and an upper edge of a rear surface thereof in a longitudinal direction, and has another positioning rib integrally mounted on a left end of the rear surface thereof. The tablet sensor board inserted between the upper positioning rib and the lower positioning rib formed on the holding member is slid from a right side of the holding member to a left side until the tablet sensor board touches at the positioning rib on a left end of the holding member, then attachment screws are inserted through the attachment holes of the tablet sensor board and threadably mounted on the screw holes in the holding member, thus the tablet sensor board is attached to the holding member. According to this structure, the board can be positioned without stud pins, so that cost of manufacturing the information processing device can be reduced.

However, because the conventional structure for mounting a board needs a plurality of positioning ribs in wide-ranging areas thereof corresponding to size of the board, the conventional structure for mounting a board has a disadvantage of high cost of manufacturing. In addition, there is a disadvantage that a positioning accuracy become worse due to accuracy variations of a plurality of the positioning ribs.

### BRIEF DESCRIPTION OF THE SEVERAL VIEWS OF THE DRAWING

A general configuration that implements the various features of the invention will now be described with reference to the drawings. The drawings and the associated descriptions are provided to illustrate embodiments of the invention and not to limit the scope of the invention.

FIG. 1 is an exemplary perspective view showing a display unit according to the embodiment of the present invention;

FIG. 2A is an exemplary front view showing a chassis mounted with kinds of circuit boards;

FIG. 2B is an exemplary enlarged view of the part A of FIG. 2A;

FIG. 2C is an exemplary enlarged view of the part B of FIG. 2A;

FIG. 3A is an exemplary cross-sectional view taken along line C-C of FIG. 2B;

FIG. 3B is an exemplary cross-sectional view taken along line D-D of FIG. 2B;

FIG. 3C is an exemplary cross-sectional view taken along line E-E of FIG. 2A;

FIG. 3D is an exemplary cross-sectional view taken along line F-F of FIG. 2A;

FIG. 4 is an exemplary front elevation view showing a chassis; and

FIG. 5 is an exemplary exploded perspective view explaining a method for mounting a board.

### DETAILED DESCRIPTION OF PREFERRED EMBODIMENTS

Various embodiments according to the invention will be described hereinafter with reference to the accompanying drawings. In general, according to one embodiment of the invention, there is provided a structure for mounting a board including: a mounting board member having a pair of positioning plates which are perpendicular to each other; and a board having a pair of slits into which a pair of the positioning plates is inserted.

According to the above structure, the board is positioned in two directions by a pair of the positioning plates which are in a direction perpendicular to each other, thereby the board can be positioned with a high degree of accuracy.

In addition, according to a further embodiment of the invention, there is also provided a structure for mounting a board including: a mounting board member having a pair of positioning plates which are perpendicular to each other, and a plurality of screw holes; and a board having a pair of slits into which a pair of the positioning plates are inserted, and a plurality of mounting holes which are formed at the position corresponding to the respective screw holes.

According to the above structure, the board is positioned in two directions by a pair of the positioning plates which are in a direction perpendicular to each other, and the board is mounted on the mounting board member by inserting screws through the mounting holes and tightening the screws into the screw holes.

In addition, according to a still further embodiment of the invention, there is also provided a structure for mounting a board including: a mounting board member having a plurality of pairs of positioning plates which are perpendicular to each other according to a plurality of boards, and a plurality of screw holes according to a plurality of the boards; and a plurality of the boards having slits into which a pair of the positioning plates is inserted, and having a plurality of mounting holes which are formed at the position corresponding to the screw holes.

According to the above structure, a plurality of the boards are positioned by the positioning plates, then a plurality of the boards are mounted on the mounting board member by inserting screws through the mounting holes and tightening the screws into the screw holes.

The positioning plates may be formed by cutting and bending a plate material. This has a merit that the boards can be positioned without other members such as stud pins and the like.

According to the present invention, the board can be positioned with a high degree of accuracy, and cost of manufacturing can be reduced.

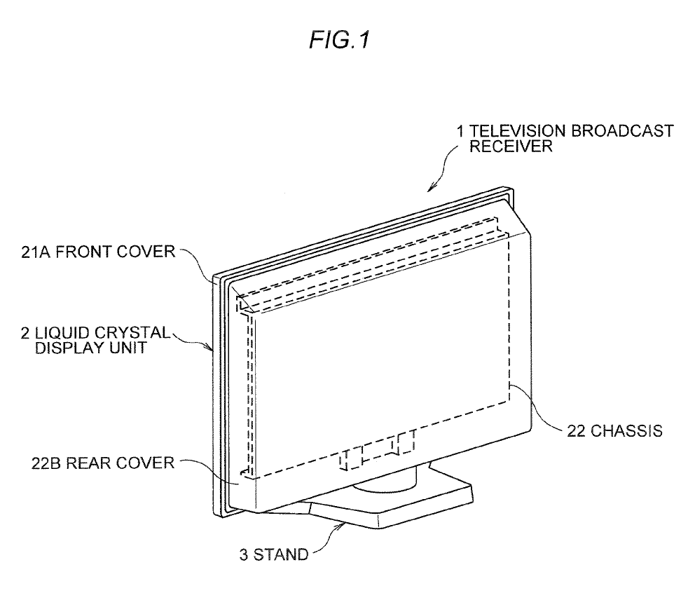

FIG. 1 is an exemplary perspective view showing a display unit having a structure for mounting a board corresponding to the embodiment of the present invention. As an example of a display unit, A television broadcast receiver will be described below, and a monitor of desktop personal computer and the like are included as the display unit.

A television broadcast receiver 1 comprises a liquid crystal display unit 2 displaying a image signal, and a stand 3 supporting the liquid crystal display unit 2 thereon.

The liquid crystal display unit 2 comprises therein a liquid crystal display displaying a image signal and a chassis 22 (as described later), which is mounted on the rear face of the liquid crystal display, having a power source, a circuit board and the like thereon which control the liquid crystal display and the like. The liquid crystal display unit 2 is equipped with a front cover 21A covering a front face of the liquid crystal display and with a rear cover 21B covering a rear face of the chassis 22. The rear cover 21B is attached to the front cover 21A using screws not shown. Another display such as a cathode-ray tube display, a plasma display, etc. may be used instead of the liquid crystal display.

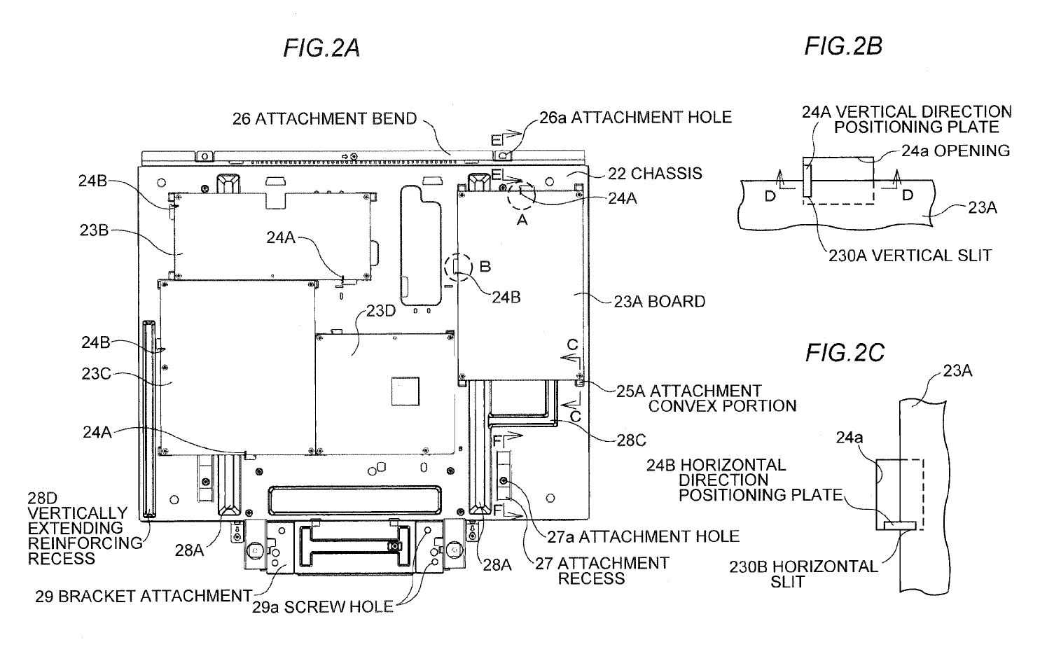

FIG. 2A is an exemplary front elevation view showing a chassis mounted with a variety of circuit boards.

FIG. 2B is an exemplary enlarged view of the part A of FIG. 2A.

FIG. 2C is an exemplary enlarged view of the part B of FIG. 2A

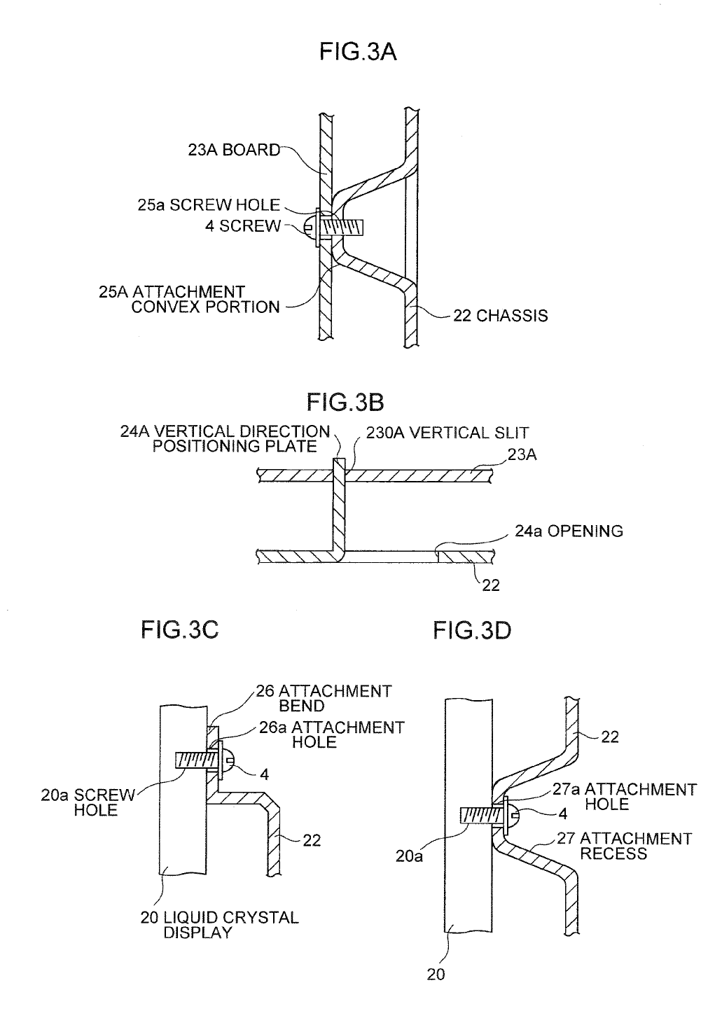

FIG. 3A is an exemplary cross-sectional view taken along line C-C of FIG. 2A.

FIG. 3B is an exemplary cross-sectional view taken along line D-D of FIG. 2B.

FIG. 3C is an exemplary cross-sectional view taken along line E-E of FIG. 2A.

FIG. 3D is an exemplary cross-sectional view taken along line F-F of FIG. 2A.

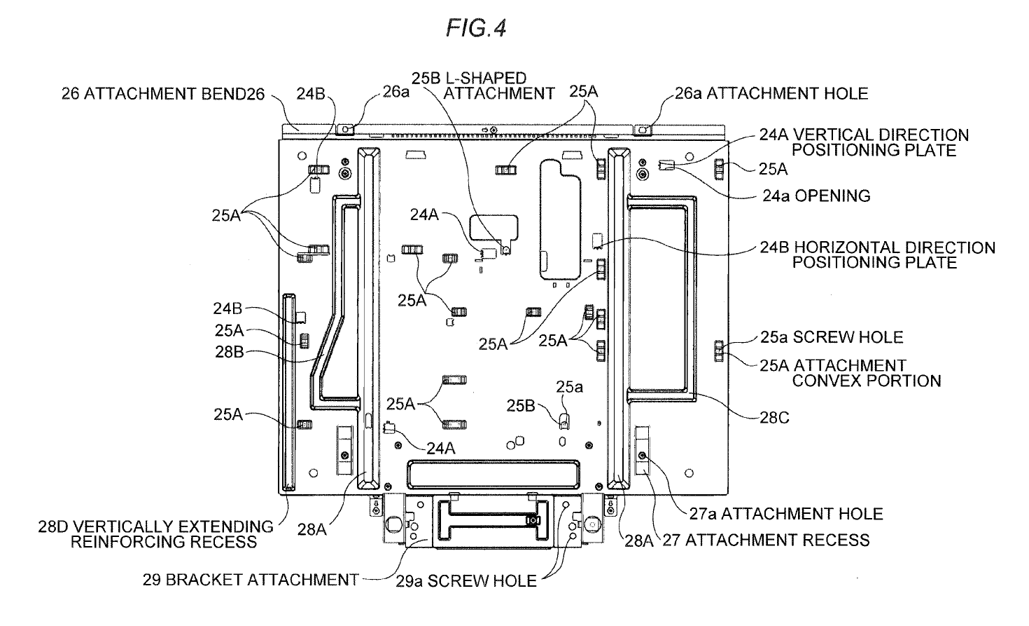

FIG. 4 is an exemplary front elevation view showing a chassis 22.

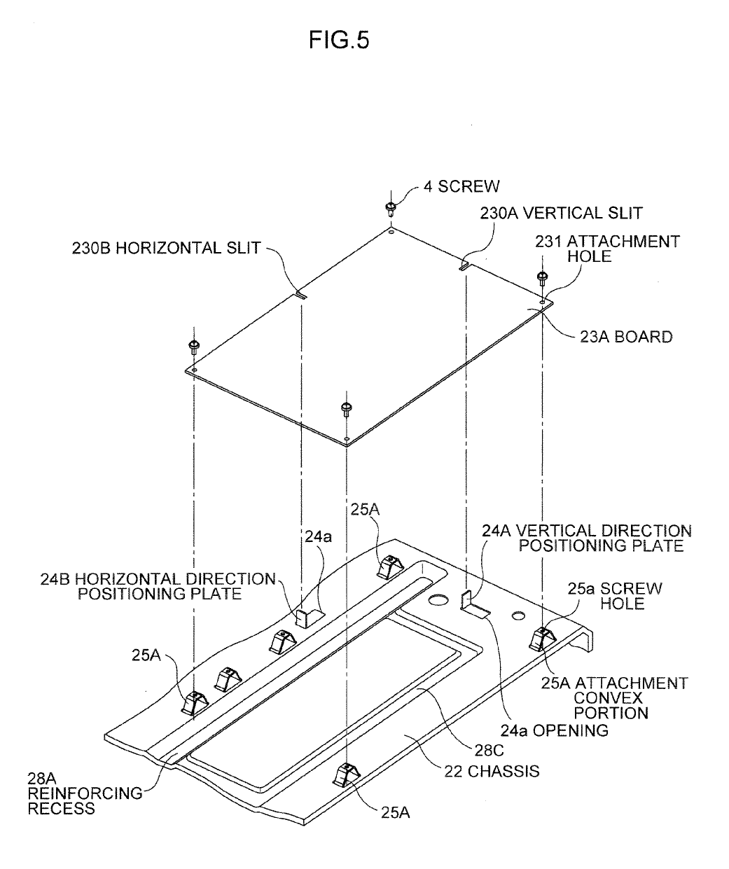

FIG. 5 is an exemplary exploded perspective view explaining a method for mounting a board.

### (Structure for Mounting Board to Chassis)

A chassis 22 includes pairs of a vertical direction positioning plates 24A and a horizontal direction positioning plates 24B according to each boards 23A, 23B and 23C, attachment convex portions 25A on which the boards 23A to 23D are mounted, and L-shaped attachment 25B. For example, the chassis 22 is manufactured from a plate 1 mm thick made of metal such as electrolytic zinc-coated carbon steel, aluminium, aluminium base alloy and the like.

The pair of a vertical direction positioning plate 24A and a horizontal direction positioning plate 24B is perpendicular to each other, and are formed by cutting and bending a part of the plate. The reference letter 24a in FIG. 2B, FIG. 2C, FIG. 3 and FIG. 4 indicates openings resulting from forming the positioning plate 24A and the positioning plate 24B.

The attachment convex portions 25A is pressed to form a convex in a direction of bending positioning plates 24A and 24B. As shown in FIG. 3A, each attachment convex portion 25A has an screw hole 25a in top area thereof. L-shaped attachment 25B is formed by cutting and bending a plate material in the form of L-shape, and has an screw hole 25a in top area thereof.

### (Structure for Mounting Chassis on Liquid Crystal Display)

As shown in FIG. 2A and FIG. 4, the chassis 22 has an attachment bend 26 and an attachment recess 27 on upper surface of the chassis 22 which contact with the liquid crystal display 20. As shown in FIG. 2A, FIG. 3C FIG. 3D and FIG. 4, the attachment bend 26 and the attachment recess 27 have an attachment hole 26a and an attachment hole 27a respectively. The chassis 22 is mounted on the rear face of the liquid crystal display 20 by inserting screws through the attachment hole 26a and the attachment hole 27a formed in the attachment bend 26 and the attachment recess 27 respectively and tightening screws into the screw holes 20a formed in the liquid crystal display 20.

### (Reinforcing Constitution of Chassis)

The chassis 22 has a pair of reinforcing recesses 28A extending in the vertical direction formed by press work. The chassis 22 has approximately C-shaped reinforcing recesses 28B and 28C connecting with a pair of the reinforcing recesses 28A respectively, and has a vertically extending reinforcing recess 28D to the right end thereof.

The chassis 22 has a bracket attachment 29 having screw holes 29a for mounting a bracket on the lower end thereof. The liquid crystal display unit 2 is attached to the stand 3 via a bracket (not shown) by inserting screws through an attachment hole of the bracket and tightening screws into the screw holes 29a of the bracket attachment 29.

### (Board)

As shown in FIG. 2, FIG. 3B and FIG. 5, each of the boards 23A, 23B and 23C except for the board 23D positioned at the lower right of FIG. 2, has a vertical slit 230A extending vertically and a horizontal slit 230B extending horizontally. As shown in FIG. 2 and FIG. 5, one end of each of the slits 230A and 230B extends to an end of the boards 23A, 23B and 23C to open. As shown in FIG. 5, the boards 23A to 23D have attachment holes 231 at four corners thereof.

When the chassis 22 is placed vertically, the vertical slit 230A is preferably located in such a position that the vertical slit 230A is at the lower end of the board. Hereby, since the horizontal direction positioning plate 24A and the vertical direction positioning plate 24B can support the weight of the boards 23A, 23B and 23C, the positioning plates 24A and 24B can easily support the boards 23A, 23B and 23C.

### (Effect of Embodiment)

The effect of the embodiment will be explained as follows.

(a) The positioning plates 24A and 24B which position the board is formed by cutting and bending a plate material at a right angle, and the attachment convex portion 25A and L-shaped attachment 25B are formed by press work or by cutting and bending a plate material. Thereby there is a merit that the boards can be positioned without other member such as stud pins and the like, so cost of manufacturing can be reduced.
(b) Since the horizontal direction of the board is positioned by the vertical direction positioning plate 24A, and the vertical direction of the board is positioned by the horizontal direction positioning plate 24B, the board can be positioned with accuracy by minimum number of the positioning plates. For example, assuming that the thickness of the positioning plate 24A and 24B is 1 mm, the width of the slit 230A and 230B is 1.2 mm, the board can be positioned to an accuracy of ±0.1 mm.
(c) Since one end of each of slit 230A and 230B leads to an end of the board to open, each of the positioning plates 24A and 24B is easily inserted into the slits 230A and 230B, so that the board can be easily attached to the chassis 22.

The present invention is not limited to the above-described embodiment. It should be understood that various changes and modifications may be made there in without departing from the scope of the invention.

For example, in the above-described embodiment, one board is positioned by one vertical direction positioning plate 24A and one horizontal direction positioning plate 24B. However, one board may be positioned by a plurality of vertical direction positioning plates 24A and one horizontal direction positioning plate 24B, by one vertical direction positioning plate 24A and a plurality of horizontal direction positioning plates 24B, or by a plurality of vertical direction positioning plates 24A and a plurality of horizontal direction positioning plates 24B, in accordance with size, shape and the like of the board.

In the above-described embodiment, a television broadcast receiver has been described as an example of the invention, the invention may apply to another electrical equipment.

What is claimed is:

1. A structure for mounting a board comprising:
a mounting board member having a pair of positioning plates which are perpendicular to each other; and
a board having a pair of slits into which a pair of the positioning plates is inserted.

2. A structure for mounting a board according to claim 1, wherein
the positioning plates is formed by cutting and bending a plate material.

3. A structure for mounting a board according to claim 1, wherein
one end of the each slits extend to an end of the board to open the end of the each slits.

4. A structure for mounting a board according to claim 1, wherein
a pair of the positioning plates is formed in such a position that the lower positioning plate is formed in the vertical direction when the mounting board member is placed vertically.

5. A structure for mounting a board according to claim 1, wherein
the width of the slit and the thickness of the positioning plate are the same.

6. A structure for mounting a board comprising:
a mounting board member having a pair of positioning plates which are perpendicular to each other, and a plurality of screw holes; and
a board having a pair of slits into which a pair of the positioning plates are inserted, and a plurality of mounting holes which are formed at the position corresponding to the respective screw holes.

7. A structure for mounting a board according to claim 6, wherein
the positioning plates is formed by cutting and bending a plate material.

8. A structure for mounting a board according to claim 6, wherein
a plurality of the screw holes are formed on top area of an attachment convex portions, which are formed by press work of the plate material at a plurality of positions to project out in the direction that the positioning plates are formed.

9. A structure for mounting a board according to claim 6, wherein
one end of the each slits extend to an end of the board to open the end of the each slits.

10. A structure for mounting a board according to claim 7, wherein
one end of the each slits extend to an end of the board to open the end of the each slits.

11. A structure for mounting a board according to claim 6, wherein
a pair of the positioning plates is formed in such a position that the lower positioning plate is formed in the vertical direction when the mounting board member is placed vertically.

12. A structure for mounting a board according to claim 6, wherein
the width of the slit and the thickness of the positioning plate are the same.

13. A structure for mounting a board comprising:
a mounting board member having a plurality of pairs of positioning plates which are perpendicular to each other according to a plurality of boards, and a plurality of screw holes according to a plurality of the boards; and
a plurality of the boards having slits into which a pair of the positioning plates are inserted, and having a plurality of mounting holes which are formed at the position corresponding to the screw holes.

14. A structure for mounting a board according to claim 13, wherein
the positioning plates is formed by cutting and bending a plate material.

15. A structure for mounting a board according to claim 13, wherein
a plurality of the screw holes are formed on top area of an attachment convex portions, which are formed by press work of the plate material at a plurality of positions to project out in the direction that the positioning plates are formed.

16. A structure for mounting a board according to claim 13, wherein
one end of the each slits extend to an end of the board to open the end of the each slits.

17. A structure for mounting a board according to claim 14, wherein
one end of the each slits extend to an end of the board to open the end of the each slits.

18. A structure for mounting a board according to claim 13, wherein
a pair of the positioning plates is formed in such a position that the lower positioning plate is formed in the vertical direction when the mounting board member is placed vertically.

19. A structure for mounting a board according to claim 13, wherein
the width of the slit and the thickness of the positioning plate are the same.
